(19) United States
(12) Patent Application Publication
(10) Pub. No.: US 2024/0065048 A1
(43) Pub. Date: Feb. 22, 2024

(54) DISPLAY DEVICE

(71) Applicant: SAMSUNG DISPLAY CO., LTD., Yongin-si (KR)

(72) Inventor: Sangyong NO, Yongin-si (KR)

(21) Appl. No.: 18/137,367

(22) Filed: Apr. 20, 2023

(30) Foreign Application Priority Data
Aug. 17, 2022 (KR) 10-2022-0102924

(51) Int. Cl. H10K 59/131

(52) U.S. Cl. CPC H10K 59/131

(57) ABSTRACT

A display device includes a substrate, a light-emitting diode disposed on the substrate, a driving transistor disposed on the substrate, electrically connected to the light-emitting diode and including a plurality of channel areas, and a plurality of lower metal layers arranged between the substrate and the driving transistor and overlapping the plurality of channel areas, respectively.

This application claims priority to Korean Patent Application No. 10-2022-0102924, filed on Aug. 17, 2022, and all the benefits accruing therefrom under 35 U.S.C. § 119, the content of which in its entirety is herein incorporated by reference.

### BACKGROUND

### 1. Field

Embodiments relate to a display device.

### 2. Description of the Related Art

Display devices display images and include liquid crystal displays (“LCDs”), organic light-emitting display devices, electrophoretic displays (“EPDs”), or the like. In general, an organic light-emitting display device includes a plurality of pixels each including an organic light-emitting diode and a thin film transistor. The organic light-emitting diode of each pixel may emit light with brightness corresponding to a driving current.

### SUMMARY

Various attempts are being made for controlling the driving current precisely. However, power consumption when attempting to precisely control the driving current.

Embodiments include a display device capable of reducing power consumption while maintaining control of brightness power. However, these objectives are exemplary, and the scope of the disclosure is not limited thereby.

Additional features will be set forth in part in the description which follows and, in part, will be apparent from the description, or may be learned by practice of the presented embodiments of the disclosure.

In an embodiment of the disclosure, a display device includes a substrate, a light-emitting diode disposed on the substrate, a driving transistor disposed on the substrate, electrically connected to the light-emitting diode and including a plurality of channel areas, and a plurality of lower metal layers arranged between the substrate and the driving transistor and overlapping the plurality of channel areas, respectively.

In an embodiment, the plurality of lower metal layers may be spaced apart from each other.

In an embodiment, the plurality of channel areas may include a first channel area and a second channel area, and the plurality of lower metal layers may include a first lower metal layer, which overlaps the first channel area and to which a first voltage is applied, and a second lower metal layer, which overlaps the second channel area and to which a second voltage having a different magnitude from that of the first voltage is applied.

In an embodiment, the first lower metal layer and the second lower metal layer may be arranged in different layers.

In an embodiment, the first lower metal layer and the second lower metal layer may overlap each other.

In an embodiment, the first lower metal layer and the second lower metal layer may be arranged in the same layer.

In an embodiment, each of the first lower metal layer and the second lower metal layer may extend in a first direction.

In an embodiment, a ratio of a width of the second channel area to a length of the second channel area may be greater than a width of the first channel area to a length of the first channel area.

In an embodiment, the display device may further include a gate conductive layer disposed on the driving transistor, and the gate conductive layer may overlap the plurality of channel areas.

In an embodiment, the driving transistor may include a silicon semiconductor layer.

In an embodiment of the disclosure, a display device includes a substrate, a first lower metal layer disposed on the substrate, a second lower metal layer disposed on the substrate and spaced apart from the first lower metal layer, a driving transistor disposed on the first lower metal layer and the second lower metal layer, and a gate conductive layer disposed on the silicon semiconductor layer. The driving transistor may include a first channel area overlapping the first lower metal layer, and a second channel area overlapping the second lower metal layer.

In an embodiment, the first lower metal layer and the second lower metal layer may be arranged in different layers.

In an embodiment, the first lower metal layer and the second lower metal layer may be arranged in the same layer.

In an embodiment, the first lower metal layer and the second lower metal layer may not overlap each other.

In an embodiment, all of the first lower metal layer and the second lower metal layer may extend in a first direction.

In an embodiment, the gate conductive layer may overlap the first channel area and the second channel area.

In an embodiment, a first voltage may be applied to the first lower metal layer, and a second voltage greater than the first voltage may be applied to the second lower metal layer.

In an embodiment, the driving transistor may include a P-channel metal oxide semiconductor (“PMOS”).

In an embodiment, a ratio of width of the second channel area to a length of the second channel area may be greater than a ratio of a width of the first channel area to a length of the first channel area.

In an embodiment, the first lower metal layer and the second lower metal layer may include the same material.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a plan view schematically illustrating an embodiment of a portion of a display device;

FIGS. 2A and 2B are equivalent circuit diagrams of an embodiment of one pixel of a display device;

FIG. 3A is a plan view schematically illustrating an embodiment of a portion of a display device;

FIGS. 3B and 3C are cross-sectional views schematically illustrating the display device, taken along line I-I′ of FIG. 3A;

FIG. 4A is a plan view schematically illustrating an embodiment of a portion of a display device;

FIG. 4B is a cross-sectional view schematically illustrating the display device, taken along line II-II′ of FIG. 4A;

FIG. 5A is a plan view schematically illustrating an embodiment of a portion of a display device;

FIG. 5B is a cross-sectional view schematically illustrating the display device, taken along line III-Ill′ of FIG. 5A; and

FIGS. 6A and 6B are graphs schematically illustrating a current-voltage curve that may be shown in an embodiment.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since various modifications and various embodiments of the disclosure are possible, illustrative embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

Hereinafter, embodiments of the disclosure will be described in detail with reference to the accompanying drawings, and the same or corresponding components are denoted by the same reference numerals, and the same reference numerals are assigned and redundant explanations will be omitted.

In the following embodiment, the terms of the first and second, etc. were used for the purpose of distinguishing one component from other components, not a limited sense.

In the following embodiment, the singular expression includes a plurality of expressions unless the context is clearly different.

In the following embodiment, the terms such as comprising or having are meant to be the features described in the specification, or the components are present, and the possibility of one or more other features or components will be added, is not excluded in advance.

In the following embodiment, when a portion such as a layer, a region, a component or the like is on other portions, this is not only when the portion is on other components, but also when other components are interposed therebetween.

In the following embodiment, the x-axis, y-axis, and z-axis are not limited to three axes on an orthogonal coordinate system, and may be interpreted in a broad sense including this case. The x-axis, the y-axis, and the z-axis may be orthogonal to each other, for example, but may refer to different directions that do not orthogonal to each other.

In the drawings, for convenience of explanation, the sizes of components may be exaggerated or reduced. Since the size and thickness of each component shown in the drawings are arbitrarily indicated for convenience of explanation, for example, the disclosure is not necessarily limited to the illustration.

In the case where some embodiments may be implemented in the specification, a specific process order may be performed differently from the order described. Two processes described in succession may be substantially performed at the same time, or in an opposite order to an order to be described, for example.

In the following embodiment, when a layer, a region, a component or the like is connected to other layers, regions or components, they are not only directly connected to other layers, regions or components but also are indirectly connected to other layers, regions or components while other layers, regions or components are interposed therebetween. In the specification, when a layer, a region, a component or the like is electrically connected to other layers, regions or components, they are not only directly electrically connected to other layers, regions or components but also are indirectly electrically connected to other layers, regions or components while other layers, regions or components are interposed therebetween, for example.

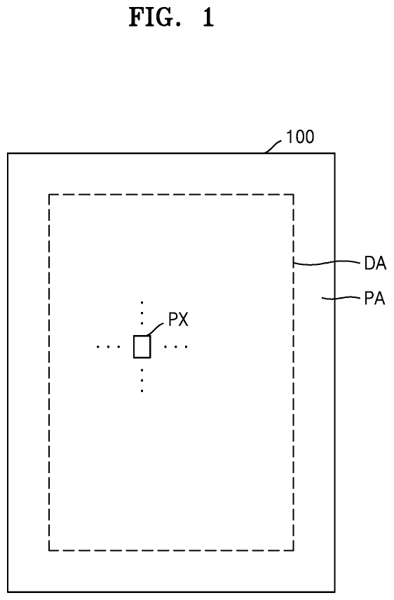

FIG. 1 is a plan view schematically illustrating an embodiment of a portion of a display device.

The display device is a device that displays an image and may be a portable mobile device, such as a game device, a multimedia device, or an ultra-compact personal computer. The display device to be described later may include a liquid crystal display (“LCD”), an electrophoretic display (“ED”), an organic light-emitting display, an inorganic electroluminescent (“EL”) display, a field emission display, a surface-conduction electron-emitter display, a quantum dot display, a plasma display, a cathode ray display, or the like. Hereinafter, an organic light-emitting display device is described in an embodiment of the display device in an embodiment, but a variety of display devices as described above may be used in embodiments.

As shown in FIG. 1, the display device may include a display area DA in which a plurality of pixels PX is arranged, and a peripheral area PA outside the display area DA. In detail, the peripheral area PA may surround an entirety of the display area DA. This may also be understood that a substrate 100 of the display device has the display area DA and the peripheral area PA.

Each of the plurality of pixels PX of the display device is a region in which light of a predetermined color may be emitted, and the display device may provide an image by light emitted from the pixels PX. In an embodiment, each pixel PX may emit red light, green light or blue light. The pixel PX may further include a plurality of thin film transistors for controlling a display element and a storage capacitor, for example. The number of thin film transistors included in one pixel may be variously modified like one to seven or the like.

The display area DA may have a polygonal shape including a quadrangular (e.g., rectangular) shape, as shown in FIG. 1. In an embodiment, the display area DA may have a rectangular shape with a longer vertical length than a horizontal length, a rectangular shape with a shorter horizontal length than a vertical length, or a square shape, for example. In an alternative embodiment, the display area DA may have various shapes such as an elliptical shape, a circular shape, or the like.

The peripheral area PA may be a non-display area in which the pixels PX are not arranged. A driver for supplying an electrical signal or power to the pixels PX may be arranged in the peripheral area PA. Pads (not shown) to which various electronic elements or printed circuit boards may be electrically connected, may be arranged in the peripheral area PA. The pads may be spaced apart from each other in the peripheral area PA and may be electrically connected to a printed circuit board or an integrated circuit element. A thin film transistor may be provided in the peripheral area PA. In this case, the thin film transistor disposed in the peripheral area PA may be a portion of a circuit unit for controlling an electrical signal applied in the display area DA.

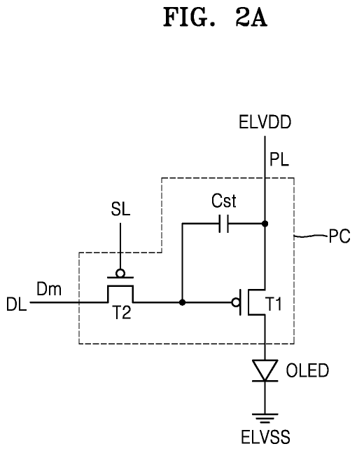

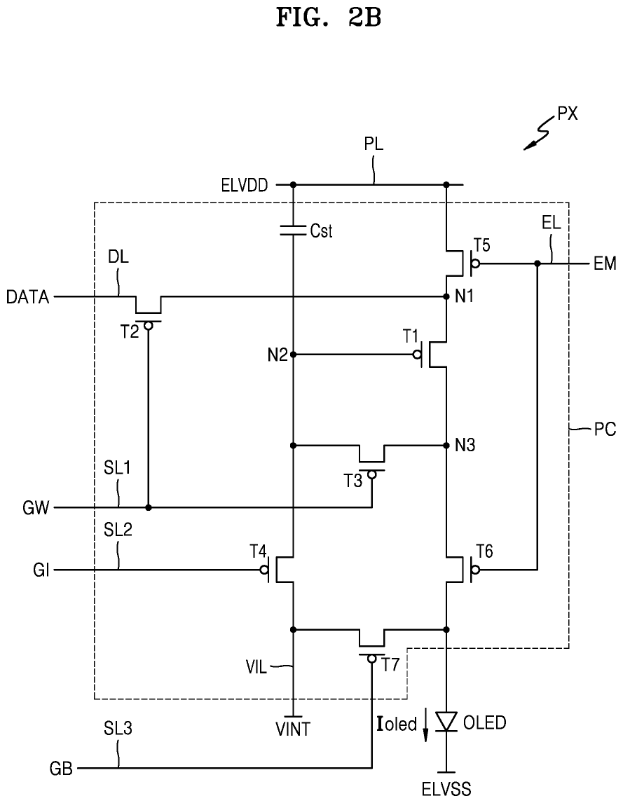

FIG. 2A is an equivalent circuit diagram of one pixel PX of the display device of FIG. 1.

As shown in FIG. 2A, one pixel PX may include a pixel circuit PC and an organic light-emitting diode OLED electrically connected to the pixel circuit PC.

The pixel circuit PC may include a first transistor T1, a second transistor T2, and a storage capacitor Cst. The second transistor T2 may be a switching transistor, may be connected to a scan line SL and a data line DL, may be turned on by a switching signal input from the scan line SL and may transmit a data signal input from the data line DL to the first transistor T1. One end of the storage capacitor Cst may be electrically connected to the second transistor T2, and the other end of the storage capacitor Cst may be electrically connected to a driving voltage line PL, and the storage capacitor Cst may store a voltage corresponding to a difference between a voltage transmitted from the second transistor T2 and a driving power supply voltage ELVDD supplied to the driving voltage line PL.

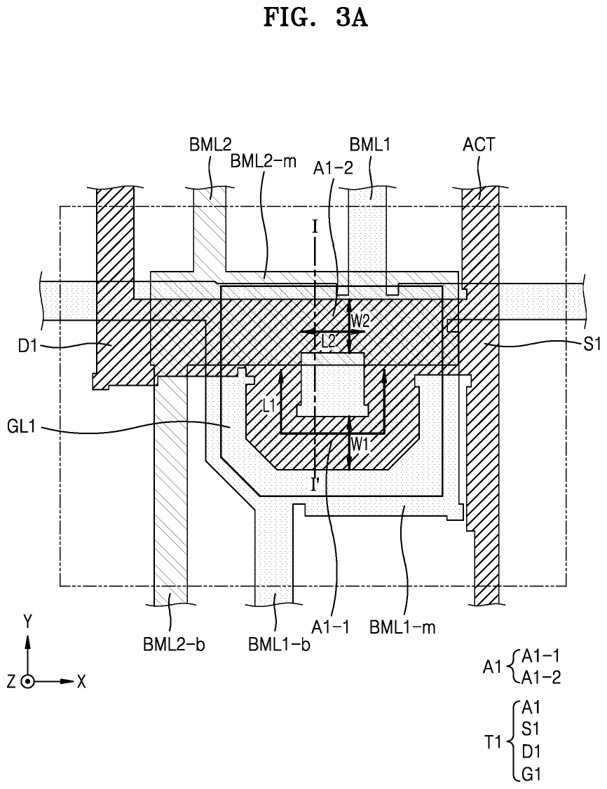

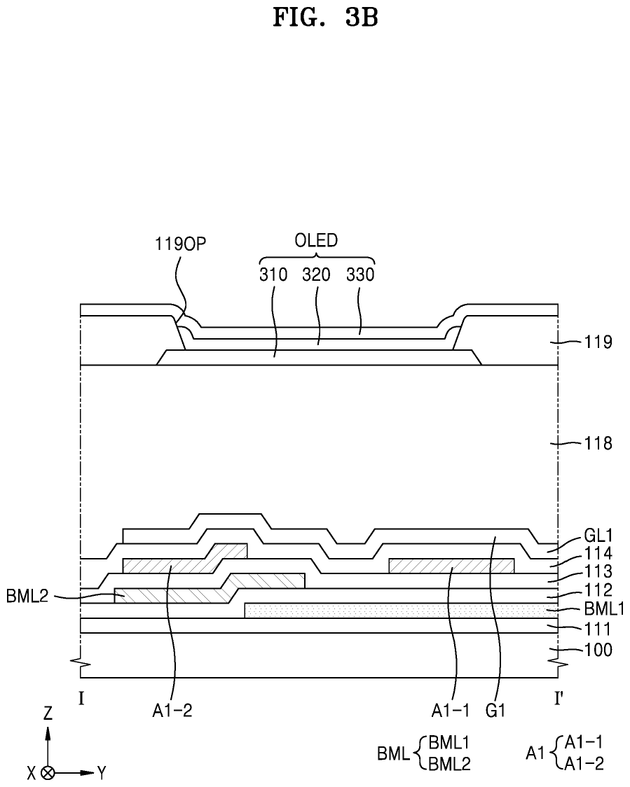

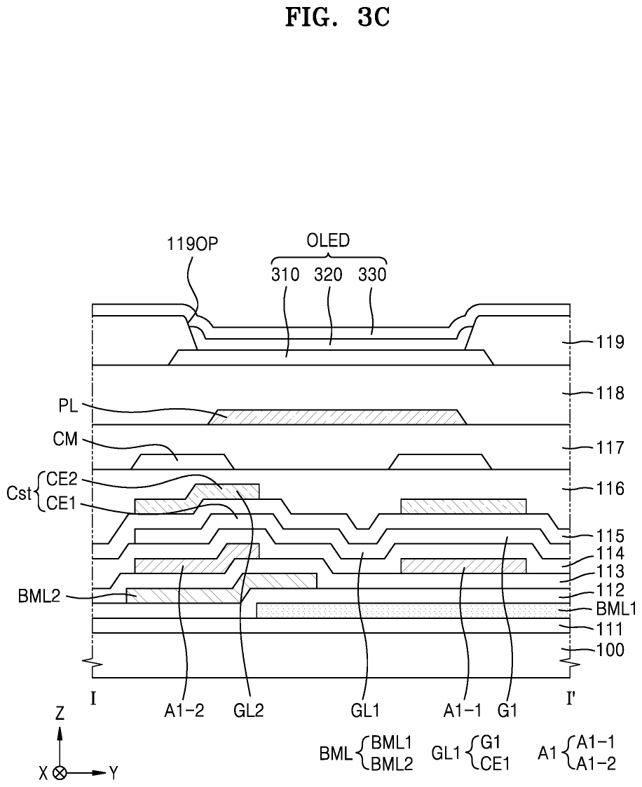

The first transistor T1 may be a driving transistor, may be connected to the driving voltage line PL and the storage capacitor Cst and may control the magnitude of the driving current flowing from the driving voltage line PL to the organic light-emitting diode OLED in response to a voltage value stored in the storage capacitor Cst. The organic light-emitting diode OLED may emit light having predetermined brightness by the driving current. An opposite electrode (refer to 330 of FIG. 3B) of the organic light-emitting diode OLED may receive an electrode power supply voltage ELVSS.

FIG. 2A illustrates that the pixel circuit PC includes two transistors and one storage capacitor. However, the disclosure is not limited thereto. In an embodiment, the number of transistors and the number of storage capacitors may be variously changed according to the design of the pixel circuit PC, for example.

FIG. 2B is an equivalent circuit diagram of one pixel PX of the display device of FIG. 1. Referring to FIG. 2B, the pixel circuit PC may include first through seventh transistors T1 to T7.

Depending on the type of transistor (N type or P type) and/or operating conditions, a first terminal of the transistor may be a source electrode or a drain electrode, and a second terminal of the first transistor may be a different electrode than the first terminal. In an embodiment, when the first terminal is a source electrode, the second terminal may be a drain electrode, for example.

The pixel circuit PC may be connected to a first scan line SL1 for transmitting a first scan signal GW, a second scan line SL2 for transmitting a second scan signal GI, a third scan line SL3 for transmitting a third scan signal GB, an emission control line EL for transmitting an emission control signal EM, a data line DL for transmitting a data signal DATA, a driving voltage line PL for transmitting the driving power supply voltage ELVDD, and an initialization voltage line VIL for transmitting an initialization voltage VINT. The pixel circuit PC may be a display element and may be connected to the organic light-emitting diode OLED.

The first transistor (or a driving transistor) T1 may be connected between the driving voltage line PL and the organic light-emitting diode OLED. The first transistor T1 may be connected between a first node N1 and a third node N3. The first transistor T1 may be connected to the driving voltage line PL via the fifth transistor T5 and may be electrically connected to the organic light-emitting diode OLED via a sixth transistor T6. The first transistor T1 may include a gate electrode connected to the second node N2, a first terminal connected to the first node N1, and a second terminal connected to the third node N3. The driving voltage line PL may transmit the driving power supply voltage ELVDD to the first transistor T1. The first transistor T1 may serve as a driving transistor and may receive the data signal DATA according to a switching operation of the second transistor T2 and may supply a driving current Ioled to the organic light-emitting diode OLED. In an embodiment, the data signal DATA may correspond to the data voltage Dm shown in FIG. 2A.

The second transistor T2 may be connected between the data line DL and the first node N1. The second transistor T2 may be connected to the driving voltage line PI via the fifth transistor T5. The second transistor T2 may include a gate electrode connected to the first scan line SL1, a first terminal connected to the data line DL, and a second terminal connected to the first node N1. The second transistor T2 may be turned on in response to the first scan signal GW transmitted through the first scan line SL1 and may perform a switching operation of transmitting the data signal DATA to the first node N1.

The third transistor T3 may be connected between the second node N2 and the third node N3. The third transistor T3 may be connected to the organic light-emitting diode OLED via the sixth transistor T6. The third transistor T3 may include a gate electrode connected to the first scan line SL1, a first terminal connected to the second node N2, and a second terminal connected to the third node N3. The third transistor T3 may be turned on in response to the first scan signal GW transmitted through the first scan line SL1 to diode-connect the first transistor T1, thereby compensating for a threshold voltage of the first transistor T1.

The fourth transistor T4 may be connected between the second node N2 and the initialization voltage line VIL. The fourth transistor T4 may include a gate electrode connected to the second scan line SL2, a first terminal connected to the second node N2, and a second terminal connected to the initialization voltage line VIL. The fourth transistor T4 may be turned on in response to the second scan signal GI transmitted through the second scan line SL2 and may transmit the initialization voltage VINT to the gate electrode of the first transistor T1, thereby initializing the gate electrode of the first transistor T1.

The fifth transistor T5 may be connected between the driving voltage line PL and the first node N1. The sixth transistor (or a second emission control transistor) T6 may be connected between the third node N3 and the organic light-emitting diode OLED. The fifth transistor T5 may include a gate electrode connected to the emission control line EL, a first terminal connected to the driving voltage line PL, and a second terminal connected to the first node N1.

The sixth transistor T6 may include a gate electrode connected to the emission control line EL, a first terminal connected to the third node N3, and a second terminal connected to a pixel electrode of the organic light-emitting diode OLED. The fifth transistor T5 and the sixth transistor T6 may be simultaneously turned on in response to the emission control signal EM transmitted through the emission control line EL so that the driving current Ioled may flow through the organic light-emitting diode OLED.

The seventh transistor T7 may be connected between the organic light-emitting diode OLED and the initialization voltage line VIL. The seventh transistor T7 may include a gate electrode connected to the third scan line SL3, a second terminal of the sixth transistor T6 and a first terminal connected to the pixel electrode of the organic light-emitting diode OLED, and a second terminal connected to the initialization voltage line VIL. The seventh transistor T7 may be turned on in response to the third scan signal GB transmitted through the third scan line SL3 and may transmit the initialization voltage VINT to the pixel electrode of the organic light-emitting diode OLED, thereby initializing the pixel electrode of the organic light-emitting diode OLED.

The capacitor Cst may include a pixel electrode connected to the gate electrode of the first transistor T1 and an opposite electrode connected to the driving voltage line PL. The capacitor Cst may store and maintain a voltage corresponding to a difference between both-end voltages of the driving voltage line PL and the gate electrode of the first transistor T1, thereby maintaining a voltage applied to the gate electrode of the first transistor T1. A boosting capacitor may be added between the second transistor T2 and the second node N2.

The organic light-emitting diode OLED may include a pixel electrode (refer to 310 of FIG. 3B) and an opposite electrode (refer to 330 of FIG. 3B), and an electrode power supply voltage ELVSS may be applied to the opposite electrode. The organic light-emitting diode OLED may receive the driving current Ioled from the first transistor T1 and may emit light, thereby displaying an image.

In FIG. 2B, the first through seventh transistors T1 to T7 are P-type transistors. The disclosure is not limited thereto. In an embodiment, the first through seventh transistors T1 to T7 may be N-type transistors, or a portion of the first through seventh transistors T1 to T7 may be N-type transistors, and the other portion of the first through seventh transistors may be P-type transistors, for example. In an embodiment, the third transistor T3 and the fourth transistor T4 among the first through seventh transistors T1 to T7 may be N-type transistors, and the others of the first through seventh transistors T1 to T7 may be P-type transistors, for example. Here, the third transistor T3 and the fourth transistor T4 may include a semiconductor layer including an oxide, and the others may include a semiconductor layer including silicon.

In the illustrated embodiment, an organic light-emitting diode is employed as a display element. However, in another embodiment, an inorganic light-emitting device or a quantum dot light-emitting device may be employed as a display element.

FIG. 3A is a plan view schematically illustrating a portion of a display device in an embodiment, and FIG. 3B is a cross-sectional view schematically illustrating the display device taken along line I-I′ of FIG. 3A.

Referring to FIGS. 3A and 3B, the display device may include a substrate 100, a first transistor including a plurality of driving channel areas A1 arranged on the substrate 100 (hereinafter, a driving transistor) T1, and a plurality of lower metal layers BML that overlap the plurality of driving channel areas A1 and are spaced apart from each other. In an embodiment, the plurality of driving channel areas A1 may include a first driving channel area A1-1 and a second driving channel area A1-2. The plurality of lower metal layers BML may include a first lower metal layer BML1 and a second lower metal layer BML2. The first lower metal layer BML1 may overlap the first driving channel area A1-1, and the second lower metal layer BML2 may overlap the second driving channel area A1-2.

The substrate 100 may include various materials such as glass, metal, plastics, or the like. In an embodiment, the substrate 100 may be a flexible substrate. In an embodiment, the substrate 100 may include polymer resin such as polyethersulphone (“PES”), polyacrylate (“PAR”), polyetherimide (“PEI”), polyethylene naphthalate (“PEN”), polyethylene terephthalate (“PET”), polyphenylene sulfide (“PPS”), polyallylate, polyimide (“PI”), polycarbonate, or cellulose acetate propionate (“CAP”), for example.

The buffer layer 111 may be disposed on the substrate 100, may reduce or prevent penetration of foreign substances, moisture or outside air from a lower portion of the substrate 100, and may provide a flat surface to the substrate 100. The buffer layer 111 may include an inorganic material such as oxide or nitride, an organic material, or an organic/inorganic composite material, and may have a single layer or multi-layer structure of the inorganic material and the organic material. A barrier layer (not shown) for preventing penetration of outside air may be further included between the substrate 100 and the buffer layer 111. In some embodiments, the buffer layer 111 may include silicon oxide (SiOₓ) or silicon nitride (SiNₓ).

The plurality of lower metal layers BML may be arranged on the substrate 100.

In an embodiment, the first lower metal layer BML1 may be disposed on the buffer layer 111. The first lower metal layer BML1 may include a first main portion BML1-m, as shown in FIG. 3A, and the first main portion BML1-m may be connected to a first branch portion BML1-b that extends in a first direction X and a second direction Y. In an embodiment, first main portions BML1-m arranged in each of adjacent pixel circuits PC may be connected to each other via the first branch portion BML1-b. In another embodiment, the first main portions BML1-m arranged in each of the adjacent pixel circuits PC may be directly connected to each other.

The first main portion BML1-m of the first lower metal layer BML1 may overlap a semiconductor layer ACT. The first main portion BML1-m of the first lower metal layer BML1 may have a shape corresponding to the driving transistor T1. The first lower metal layer BML1 may overlap the first driving channel area A1-1 of the driving transistor T1. The first main portion BML1-m of the first lower metal layer BML1 may be a portion of the semiconductor layer ACT and may serve as a lower protection metal for protecting portions that overlap the first lower metal layer BML1.

The first lower metal layer BML1 may include a light-shielding material. The first lower metal layer BML1 may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, the first lower metal layer BML1 may have a single layer structure of Mo or a double layer structure including a stack of a Mo layer and a Ti layer, or may have a triple layer structure including a stack of a Ti layer, an Al layer, and a Ti layer. A first lower insulating layer 112 may cover the first lower metal layer BML1 and may be disposed on the buffer layer 111.

A second lower metal layer BML2 may be disposed on the first lower insulating layer 112.

The second lower metal layer BML2 may include a second main portion BML2-m, as shown in FIG. 3A, and the second main portion BML2-m may be connected to a second branch portion BML2-b that extends in the second direction Y. Unlike illustration, the second branch portion BML2-b may also extend in the first direction X.

Second main portions BML2-m arranged in each of the adjacent pixel circuits PC may be connected to each other via the second branch portion BML2-b. In another embodiment, the second main portions BML2-m arranged in each of the adjacent pixel circuits PC may be directly connected to each other.

The second main portion BML2-m of the second lower metal layer BML2 may overlap the semiconductor layer ACT. The second main portion BML2-m of the second lower metal layer BML2 may have a shape corresponding to the driving transistor T1. The second lower metal layer BML2 may overlap the second driving channel area A1-2 of the driving transistor T1. The second main portion BML2-m of the second lower metal layer BML2 may be a portion of the semiconductor layer ACT and may serve as a lower protection metal for protecting portions that overlap the second lower metal layer BML2.

The second lower metal layer BML2 may include a light-shielding material. The second lower metal layer BML2 may include at least one of Al, Pt, Pd, Ag, Mg, Au, Ni, Nd, Ir, Cr, Li, Ca, Mo, Ti, W, and Cu. In some embodiments, the first lower metal layer BML1 may have a single layer structure of Mo or a double layer structure including a stack of a Mo layer and a Ti layer, or may have a triple layer structure including a stack of a Ti layer, an Al layer, and a Ti layer. The second lower insulating layer 113 may cover the second lower metal layer BML2 and may be disposed on the first lower insulating layer 112.

The semiconductor layer ACT may be disposed on a plurality of lower metal layers BML with at least one insulating layer therebetween. The semiconductor layer ACT may be disposed on the second lower insulating layer 113. The semiconductor layer ACT may include a silicon semiconductor.

A partial region of the semiconductor layer ACT may correspond to a semiconductor area of the driving transistor T1. The semiconductor layer ACT may include a channel area, and a source area and a drain area at opposite sides of the channel area. In an embodiment, the source area and the drain area may be doped with an impurity, and the impurity may include an N-type impurity and a P-type impurity. The source area and the drain area may be understood as a source electrode and a drain electrode of a transistor. Hereinafter, for convenience of explanation, the source electrode and the drain electrode will be described as a source area and a drain area, respectively.

The driving transistor T1 may include a driving channel area A1, a driving source area S1 and a driving drain area D1 at opposite sides of the driving channel area A1, and a driving gate electrode G1 that overlaps the driving channel area A1. A plurality of driving channel areas A1 may be provided. The plurality of driving channel areas A1 may include a first driving channel area A1-1 and a second driving channel area A1-2.

The driving transistor T1 may control the magnitude of a current flowing through the light-emitting device based on the data voltage Dm. The data voltage Dm may be output by a data driving unit (not shown) and may be received by the pixel PX through the data line DL. The light-emitting device may emit light with brightness corresponding to the magnitude of the current received from the driving transistor T1 so that the pixel PX may represent a gradation corresponding to the data voltage Dm.

Referring to FIG. 3A, a ratio (W2/L2) of a width W2 of the second driving channel area A1-2 to a length L2 of the second driving channel area A1-2 may be greater than a ratio (MU) of a width W1 of the first driving channel area A1-1 to a length L1 of the first driving channel area A1-1. The first driving channel area A1-1 may include a shape such as an omega shape, thereby maintaining a long channel length in a narrow space. When the length of the first driving channel area A1-1 is long, a driving range of the data voltage Dm is increased so that the gradation of light emitted from the light-emitting device may be precisely controlled and a display quality may be enhanced. In particular, this may be effective in a low gradation region that is sensitive to the data voltage Dm. However, when the driving range of the data voltage Dm is increased, power consumption thereby may also be increased.

In an embodiment, the first driving channel area A1-1 may overlap the first lower metal layer BML1, and the second driving channel area A1-2 may overlap the second lower metal layer BML2. The first driving channel area A1-1 may overlap the first main portion BML1-m, and the second driving channel area A1-2 may overlap the second main portion BML2-m. The first lower metal layer BML1 and the second lower metal layer BML2 may be spaced apart from each other.

A first voltage may be applied to the first lower metal layer BML1, and a second voltage having a different magnitude from the first voltage may be applied to the second lower metal layer BML2. Thus, one of the first driving channel area A1-1 and the second driving channel area A1-2 may operate from the data voltage Dm of a relatively low gradation, and the other one may start operating from the data voltage Dm of a higher gradation. That is, in a low gradation region, only one channel may operate, and in a high gradation region, all channels may operate. The first voltage and the second voltage may be applied within a range of ±2 volts (V) at the driving power supply voltage ELVDD.

In an embodiment, when the driving transistor T1 is provided as a p-channel metal oxide semiconductor (“PMOS”), when a negative (−) voltage may be applied to the first lower metal layer BML1 disposed under the driving transistor T1 and a positive (+) voltage is applied to the second lower metal layer BML2, due to a change in a threshold voltage Vth of the driving transistor T1, only the first driving channel area A1-1 may operate in the data voltage Dm of the low gradation, and the second driving channel area A1-2 may operate together in the data voltage Dm of the high gradation, for example.

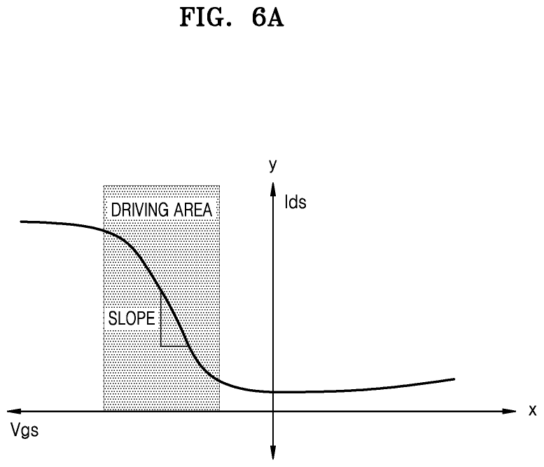

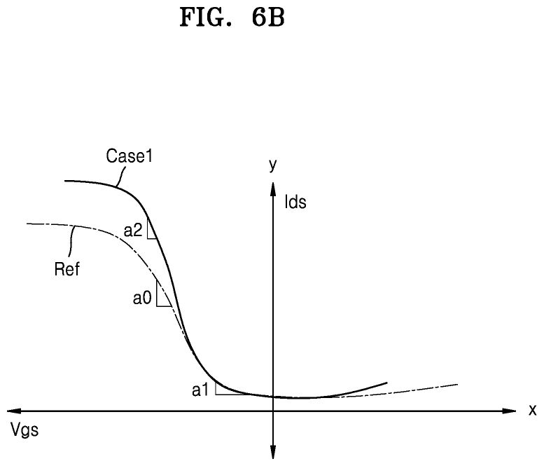

That is, in the high gradation region, all of the two channel areas A1-1 and A1-2 may operate so that a current may be increased. Thus, the entirety of the driving range of the data voltage Dm may be reduced. Thus, control of brightness power in the low gradation region that is relatively sensitive to the data voltage Dm may be maintained, and an increase in power consumption by the driving range of the data voltage Dm may be minimized. By controlling the magnitude of the voltage applied to the plurality of lower metal layers BML1 and BML2 disposed in each of the channel areas A1-1 and A1-2, a more precise design may be made. A detailed description thereof will be provided below with reference to the graphs of FIGS. 6A and 6B.

Referring to FIG. 3A, the first lower metal layer BML1 and the second lower metal layer BML2 may be arranged in different layers. The first lower metal layer BML1 and the second lower metal layer BML2 may overlap each other. The second lower metal layer BML2 is disposed on the first lower metal layer BML1. However, in another embodiment, the first lower metal layer BML1 may be disposed on the second lower metal layer BML2.

A first gate insulating layer 114 may be disposed on the semiconductor layer ACT. In other words, the first gate insulating layer 114 may cover the semiconductor layer ACT. The first gate insulating layer 114 may include an inorganic insulating material such as silicon oxide (SiOₓ), silicon nitride (SiNₓ), silicon oxynitride (SiOₓ N_{y}), aluminum oxide (Al₂O₃), titanium oxide (TiO₂), tantalum oxide (Ta₂O₅), hafnium oxide (HfO₂), and/or zinc oxide (ZnO).

A first gate conductive layer GL1 may be disposed on the first gate insulating layer 114. The first gate conductive layer GL1 may include a low-resistivity metal material. In an embodiment, the first gate conductive layer GL1 may include a conductive material including Mo, Al, Cu, or Ti, and may have a multi-layer or single layer structure including the above-described materials.

In an embodiment, the first gate conductive layer GL1 may include a driving gate electrode G1. The driving gate electrode G1 may overlap the semiconductor layer ACT. The driving gate electrode G1 may overlap the plurality of channel areas A1 of the driving transistor T1. The driving gate electrode G1 may overlap the first driving channel area A1-1 and the second driving channel area A1-2.

A planarization layer 118 may be disposed on the first gate conductive layer GL1.

The planarization layer 118 may include a flat top surface on which the pixel electrode 310 may be flatly formed. The planarization layer 118 may have a single layer or multi-layer structure including a layer including or consisting of an organic material or inorganic material. The planarization layer 118 may include a general use polymer such as benzocyclobutene (“BCB”), polyimide, hexamethyldisiloxane (“HMDSO”), polymethylmethacrylate (“PMMA”) or polystyrene (“PS”), a polymer derivative having a phenol-based group, an acryl-based polymer, an imide-based polymer, an aryl ether-based polymer, a fluorine-based polymer, a p-xylene-based polymer, a vinyl alcohol-based polymer, or any combinations thereof. The planarization layer 118 may include silicon oxide (SiOₓ), silicon nitride (SiNₓ), silicon oxynitride (SiOₓ N_{y}), aluminum oxide (Al₂O₃), titanium oxide (TiO₂), tantalum oxide (Ta₂O₅), hafnium oxide (HfO₂), or zinc oxide (ZnO₂). After the planarization layer 118 is formed, chemical mechanical polishing may be performed to provide a flat top surface.

An opening for exposing one of the source electrode S1 and the drain electrode D1 of the first transistor T1 may be defined in the planarization layer 118. The pixel electrode 310 may contact the source electrode S1 or the drain electrode D1 through the opening and may be electrically connected to the driving transistor T1.

The organic light-emitting diode OLED may be disposed on the planarization layer 118. The organic light-emitting diode OLED may include a pixel electrode 310, an intermediate layer 320 including an organic light-emitting layer, and an opposite electrode 330.

The pixel electrode 310 may include a light-transmitting conductive layer including or consisting of a light-transmitting conductive oxide such as ITO, In₂O₃ or IZO, and a reflective layer including or consisting of metal such as A1 or Ag. In an embodiment, the pixel electrode 310 may have a three-layer structure of ITO/Ag/ITO. A pixel-defining layer 119 may be disposed on the pixel electrode 310, for example.

The pixel-defining layer 119 may define a pixel by defining an opening 1190P corresponding to each sub-pixel, i.e., the opening 1190P through which at least the center of the pixel electrode 310 is exposed. Also, the pixel-defining layer 119 may increase a distance between an edge of the pixel electrode 310 and the opposite electrode 330, thereby preventing an arc from occurring therebetween. The pixel-defining layer 119 may include an organic material such as polyimide or HMDSO.

A spacer (not shown) may be disposed on the pixel-defining layer 119. The spacer may be used to prevent imprinting of masks that may occur during a mask process desired for the formation of the intermediate layer 320 of the organic light-emitting diode OLED. The spacer may include an organic material such as polyimide or HMDSO. The spacer may be simultaneously formed with the same material as that of the pixel-defining layer 119. In this case, a halftone mask may be used.

The intermediate layer 320 may include an emission layer. The organic light-emitting layer may include an organic material including fluorescent or phosphorescent material that emits red light, green light or white light. The green light may be a light belonging to a wavelength band of 495 nanometers (nm) to 580 nm, the red light may be a light belonging to a wavelength band of 580 nm to 780 nm, and the blue light may be a light belonging to a wavelength band of 400 nm to 495 nm.

The organic light-emitting layer may be a small molecular weight organic material or polymer organic material, and a functional layer such as a hole transport layer (“HTL”), a hole injection layer (“HIL”), an electron transport layer (“ETL”), and an electron injection layer (“EIL”), may be selectively further disposed under and on the organic light-emitting layer. The intermediate layer 320 may correspond to each of a plurality of pixel electrodes 310. However, the disclosure is not limited thereto. The intermediate layer 320 may include a variety of modifications, such as a layer that is integrated throughout the plurality of pixel electrode 310.

The opposite electrode 330 may be disposed throughout the display area (refer to DA of FIG. 1) and the peripheral area (refer to PA of FIG. 1) and may be disposed on the intermediate layer 320 and the pixel-defining layer 119. The opposite electrode 330 may be unitary with the plurality of organic light-emitting diodes OLED as a single body to correspond to the plurality of pixel electrodes 310.

The opposite electrode 330 may cover the intermediate layer 320. The opposite electrode 330 may be a light-transmitting electrode or reflective electrode. In some embodiments, the opposite electrode 330 may be a transparent or semi-transparent electrode, and may include or consist of a metal thin film having a relatively small work function including Li, Ca, LiF/Ca, LiF/Al, Al, Ag, Mg, or any combinations thereof. Also, a transparent conductive oxide (“TCO”) layer such as ITO, IZO, ZnO or In₂O₃ may be further disposed on the metal thin film.

Referring to FIG. 3C, in an embodiment, the display device may include a substrate 100, a driving transistor T1 (refer to FIG. 3A) that is disposed on the substrate 100 and includes a plurality of channel areas A1, and a plurality of lower metal layers BML that overlap the plurality of channel areas A1, respectively. A redundant description with FIG. 3B is omitted.

The plurality of lower metal layers BML may be spaced apart from each other. The plurality of lower metal layers BML may include a first lower metal layer BML1 and a second lower metal layer BML2. The first lower metal layer BML1 and the second lower metal layer BML2 may be disposed in different layers. The second lower metal layer BML2 may be disposed on the first lower metal layer BML1. The first lower metal layer BML1 and the second lower metal layer BML2 may overlap each other. A first voltage may be applied to the first lower metal layer BML1, and a second voltage having a different magnitude from the first voltage may be applied to the second lower metal layer BML2.

The driving transistor T1 may be disposed on the plurality of lower metal layers BML. The driving transistor T1 may include a first driving channel area A1-1 and a second driving channel area A1-2. A ratio (MU) of a width of the first driving channel area A1-1 to a length of the first driving channel area A1-1 may be less than a ratio (W2/L2) of a width of the second driving channel area A1-2 to a length of the second driving channel area A1-2. The first driving channel area A1-1 may overlap the first lower metal layer BML1, and the second driving channel area A1-2 may overlap the second lower metal layer BML2.

In an embodiment, a first voltage may be applied to the first lower metal layer BML1, and a second voltage that is greater than the first voltage may be applied to the second lower metal layer BML2. In this case, in the first driving channel area A1-1 that overlaps the first lower metal layer BML1, an operation may start from the data voltage Dm of a lower gradation than the second driving channel area A1-2 that overlaps the second lower metal layer BML2.

A first gate conductive layer GL1 may be disposed on the driving transistor T1. The first gate conductive layer GL1 may include a driving gate electrode G1. The driving gate electrode G1 may overlap the channel area A1 of the driving transistor T1. The driving gate electrode G1 may overlap the first driving channel area A1-1 and the second driving channel area A1-2. A second gate insulating layer 115 may be disposed on the first gate conductive layer GL1.

Referring to FIG. 3C, the second gate conductive layer GL2 may be disposed on the first gate conductive layer GL1 with at least one insulating layer therebetween. A second gate conductive layer GL2 may be disposed on the second gate insulating layer 115. The second gate conductive layer GL2 may include a second electrode CE2 of the storage capacitor Cst. The second gate insulating layer 115 may serve as a dielectric layer of the storage capacitor Cst.

The second electrode CE2 may overlap the driving gate electrode G1 and may include the storage capacitor Cst together with the driving gate electrode G1. The storage capacitor Cst may include a first electrode CE1 and a second electrode CE2, and the first electrode CE1 may be a driving gate electrode G1. That is, the first electrode CE1 may be provided integrally with the driving gate electrode G1. In this case, the storage capacitor Cst may overlap the driving transistor T1.

The storage capacitor Cst may include the first electrode CE1 and the second electrode CE2. The first electrode CE1 of the storage capacitor Cst may be electrically connected to the driving gate electrode G1 of the driving transistor T1, and the second electrode CE2 of the storage capacitor Cst may be electrically connected to the driving voltage line PL. An electric charge corresponding to a difference between a voltage of the driving gate electrode G1 of the driving transistor T1 and the driving power supply voltage ELVDD may be stored in the storage capacitor Cst.

The inter-insulating layer 116 may be formed on the entirety of the surface of the substrate 100 to cover the second electrode CE2. The inter-insulating layer 116 may include silicon oxide (SiOₓ), silicon nitride (SiNₓ), silicon oxynitride (SiOₓ N_{y}), aluminum oxide (Al₂O₃), titanium oxide (TiO₂), tantalum oxide (Ta₂O₅), hafnium oxide (HfO₂), or zinc oxide (ZnO₂).

A connection electrode layer CM may be disposed on the inter-insulating layer 116. The connection electrode layer CM may include a source electrode and a drain electrode. The source electrode and the drain electrode may include a conductive material including Mo, Al, Cu, or Ti, and may have a multi-layer or single layer structure including the above-described materials. In an embodiment, the source electrode and the drain electrode may have a multi-layer structure of Ti/Al/Ti. A lower planarization layer 117 may be disposed on the connection electrode layer CM. The driving voltage line PL may be disposed on the lower planarization layer 117.

The planarization layer 118 may be disposed on the driving voltage line PL. A pixel-defining layer 119 in which an opening 1190P for exposing at least a portion of the pixel electrode 310 is defined may be disposed on the planarization layer 118. An organic light-emitting diode OLED including a pixel electrode 310, an intermediate layer 320, and an opposite electrode 330 may be disposed on the planarization layer 118.

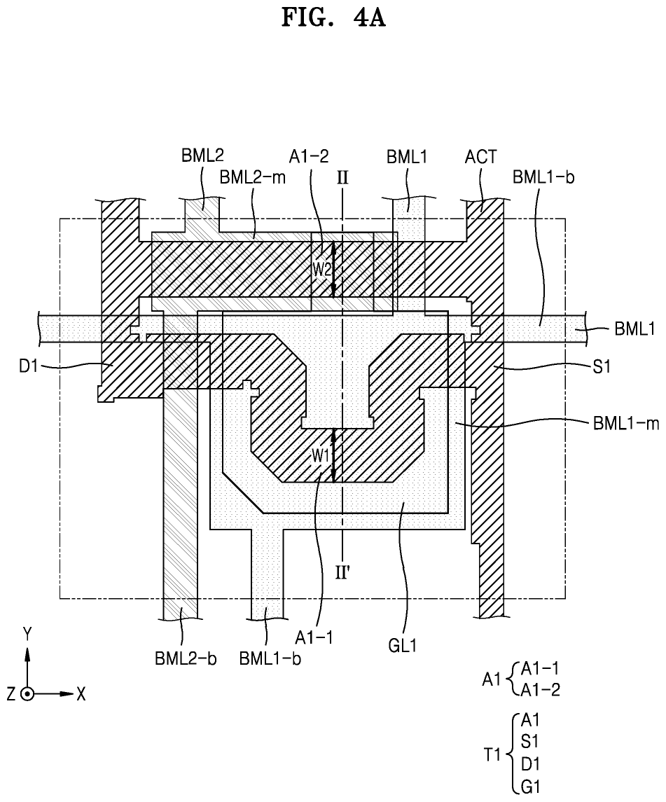

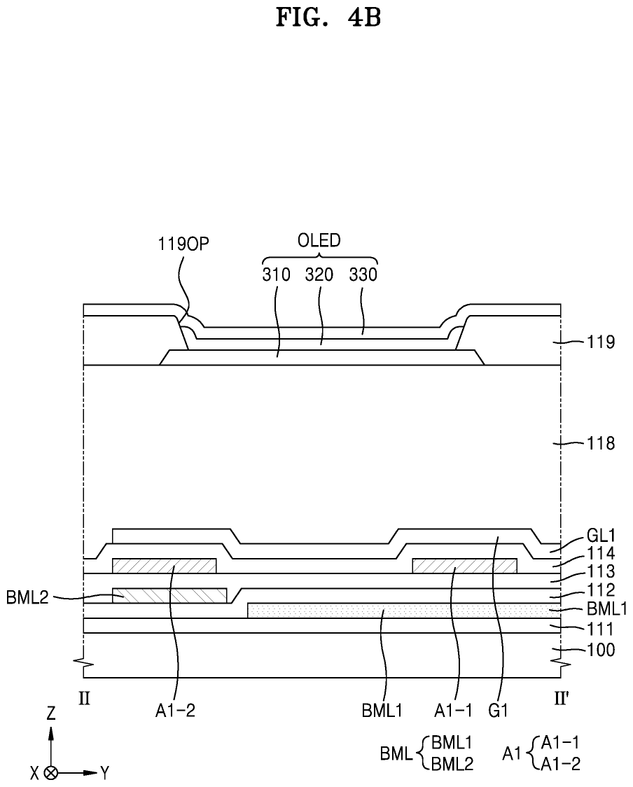

FIG. 4A is a plan view schematically illustrating an embodiment of a portion of a display device, and FIG. 4B is a cross-sectional view schematically illustrating the display device taken along line II-II′ of FIG. 4A. A redundant description with the same configuration of FIGS. 3A through 3C is omitted.

Referring to FIGS. 4A and 4B, a display device in an embodiment may include a substrate 100, a plurality of lower metal layers BML arranged on the substrate 100, and a driving transistor T1 having a plurality of driving channel areas A1.

The plurality of lower metal layers BML may include a first lower metal layer BML1 and a second lower metal layer BML2. The first lower metal layer BML1 and the second lower metal layer BML2 may be spaced apart from each other. Voltages having different magnitudes may be applied to the first lower metal layer BML1 and the second lower metal layer BML2.

Referring to FIG. 4A, the first lower metal layer BML1 may include a first main portion BML1-m, and the first main portion BML1-m may be connected to a first branch portion BML1-b that extends in a first direction X and/or a second direction Y. In an embodiment, first main portions BML1-m arranged in each of adjacent pixel circuits PC may be connected to each other via the first branch portion BML1-b. In another embodiment, the first main portions BML1-m arranged in each of the adjacent pixel circuits PC may be directly connected to each other.

The second lower metal layer BML2 may include a second main portion BML2-m, and the second main portion BML2-m may be connected to a second branch portion BML2-b that extends in the first direction X and/or the second direction Y. Second main portions BML2-m arranged in each of the adjacent pixel circuits PC may be connected to each other via the second branch portion BML2-b. In another embodiment, the second main portions BML2-m arranged in each of the adjacent pixel circuits PC may be directly connected to each other.

The driving transistor T1 may include a first driving channel area A1-1 and a second driving channel area A1-2. The first driving channel area A1-1 may overlap the first lower metal layer BML1, and the second driving channel area A1-2 may overlap the second lower metal layer BML2.

A first gate conductive layer GL1 may be disposed on the driving transistor T1. A portion of the first gate conductive layer GL1 overlapping the plurality of driving channel areas A1 may be a driving gate electrode G1.

In an embodiment shown in FIGS. 4A and 4B, a distance between the first driving channel area A1-1 and the second driving channel area A1-2 may be greater than that of the embodiment shown in FIG. 3A. Thus, the first lower metal layer BML1 and the second lower metal layer BML2 may not overlap each other. A first gate conductive layer GL1 including the driving gate electrode G1 may overlap the first driving channel area A1-1 and the second driving channel area A1-2.

FIG. 4B illustrates that the planarization layer 118 is disposed on the first gate conductive layer GL1. However, as shown in FIG. 3C, the display device may further include a second gate conductive layer GL2 including the second electrode CE2 of the storage capacitor Cst, the connection electrode layer CM including the source electrode and the drain electrode, and a driving voltage line PL, and a data line (refer to DL of FIG. 2B).

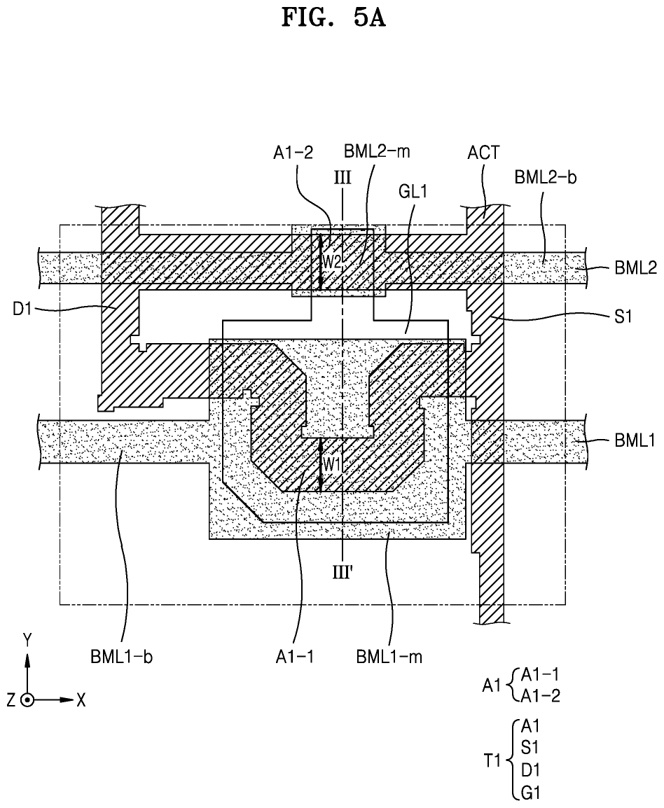

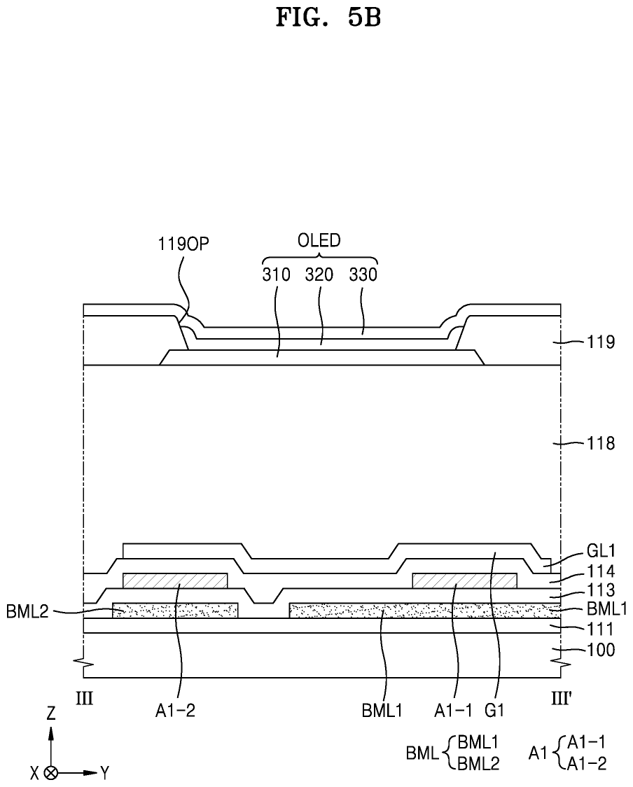

FIG. 5A is a plan view schematically illustrating an embodiment of a portion of a display device, and FIG. 5B is a cross-sectional view schematically illustrating the display device taken along line III-Ill′ of FIG. 5A. A redundant description with the same configuration of FIGS. 3A through 3C is omitted.

Referring to FIGS. 5A and 5B, the display device in an embodiment may include a substrate 100, a plurality of lower metal layers BML arranged on the substrate 100, a driving transistor T1 including a plurality of driving channel areas A1 each corresponding to the plurality of lower metal layers, and a first gate conductive layer GL1 that overlap the plurality of driving channel areas A1.

Referring to FIG. 5A, the first lower metal layer BML1 may include a first main portion BML1-m, and the first main portion BML1-m may be connected to a first branch portion BML1-b that extends in a first direction X. In an embodiment, first main portions BML1-m arranged in each of adjacent pixel circuits PC may be connected to each other via the first branch portion BML1-b. The second lower metal layer BML2 may include a second main portion BML2-m, and the second main portion BML2-m may be connected to a second branch portion BML2-b that extends in the first direction X and/or the second direction Y. Second main portions BML2-m arranged in each of the adjacent pixel circuits PC may be connected to each other via the second branch portion BML2-b.

Referring to FIG. 5B, the first lower metal layer BML1 and the second lower metal layer BML may be disposed on the substrate 100. The first lower metal layer BML1 and the second lower metal layer BML2 may be disposed in the same layer. The first lower metal layer BML1 and the second lower metal layer BML2 may include the same material. Referring to FIG. 5A, all of the first main portion BML1-m of the first lower metal layer BML1 and the second main portion BML2-m of the second lower metal layer BML2 may extend in the first direction. Thus, the first lower metal layer BML1 and the second lower metal layer BML2 may not overlap each other. The first gate conductive layer GL1 may overlap all of the first driving channel area A1-1 and the second driving channel area A1-2.

FIG. 5B illustrates that the planarization layer 118 is disposed on the first gate conductive layer GL1. However, as shown in FIG. 3C, the display device may further include a second gate conductive layer GL2 including the second electrode CE2 of the storage capacitor Cst, the connection electrode layer CM including the source electrode and the drain electrode, and a driving voltage line PL, and a data line (refer to DL of FIG. 2B).

FIGS. 6A and 6B are graphs schematically illustrating a current-voltage curve I-V curve that may be shown in an embodiment.

First, a portion of an operating procedure of one pixel of the display device will be described below with reference to FIG. 2.

During a data writing period in which the first scan signal GW at a low level is received, the second transistor T2 and the third transistor T3 may be turned on, and the data voltage Dm may be received by a source of the driving transistor (or the first transistor) T1. The driving transistor T1 may be diode-connected by the third transistor T3, and may be biased in a forward direction.

When the gate voltage of the driving transistor T1 is the same as a data compensation voltage (Dm−|Vth|) in which the data voltage Dm is reduced by a threshold voltage Vth of the driving transistor T1, the driving transistor T1 may be turned off, and an increase in the gate voltage of the driving transistor T1 may stop. Thus, a difference (ELVDD−Dm+|Vth|) between the driving power supply voltage ELVDD and the data compensation voltage (Dm−|Vth|) may be stored in the storage capacitor Cst.

Thereafter, when the emission control signal EM at a low level is received, the fifth transistor T5 and the sixth transistor T6 may be turned on, and the driving transistor T1 may output a driving current Ids that corresponds to a voltage (ELVDD−Dm) obtained by subtracting the threshold voltage |Vth| of the driving transistor T1 from the voltage stored in the storage capacitor Cst, i.e., a source-gate voltage (ELVDD−Dm+|Vth|) of the driving transistor T1, and the organic light-emitting diode OLED may emit light corresponding to the magnitude of the driving current Ids.

In the graphs of FIGS. 6A and 6B, the x-axis represents a source-gate voltage Vgs of the driving transistor T1, and the y-axis represents the driving current Ids. A driving area of the source-gate voltage Vgs (ELVDD−Dm+|Vth|) of the driving transistor T1 may correspond to the driving range of the data voltage Dm. That is, in FIGS. 6A and 6B, the narrowing or wider driving region of the source-gate voltage Vgs of the driving transistor T1 is interpreted as narrowing or expanding the driving range of the data voltage Dm.

Since the power consumption by the data line DL is square proportional of the driving range of the data voltage Dm, the power consumption may increase when the driving range of the data voltage Dm increases.

When a slope in the graph of FIG. 6A is set to be gentle, it is easy to control the driving current Ids through the data voltage Dm so that control of light gradation power may be increased. However, the driving area of the source-gate voltage Vgs of the driving transistor T1 increases. That is, the driving range of the data voltage Dm may be increased. As the driving range of the data voltage Dm increases, power consumption may increase.

On the contrary, in the graph of FIG. 6A, the slope is set to be steep, the power consumption may be reduced as the driving range of the data voltage Dm is narrowed, but control of gradation power is lowered.

Referring to FIGS. 3A through 5B, in an embodiment, the display device may include a driving transistor T1 including a plurality of driving channel areas A1, and a plurality of lower metal layers BML that overlap the plurality of channel areas A1, respectively. Voltages having different magnitudes may be applied to the plurality of lower metal layers BML. When voltages having different magnitudes are applied to the plurality of lower metal layers BML that overlap the plurality of driving channel areas A1, respectively, a change occurs in the threshold voltage |Vth| of the driving transistor T1, and the range of gradation in which the plurality of driving channel areas A1 operates, may be different. That is, in a low gradation region, only one channel may operate, and in a high gradation region, all channels may operate. As all channel areas operate, the overall amount of currents may increase. In the graph of FIG. 6A, only the slope in the high gradation region may be increased.

Referring to FIG. 6B, in the case of a comparative example Ref, the slope a0 of the graph is overall set to be low. Thus, control of gradation power may be increased but power consumption may also increase. Unlike this, the graph in an embodiment (Case1) of the disclosure has a gentle slope a1 in a low gradation and a comparatively steep slope a2 in a relatively high gradation. That is, the slope a1 of a low gradation region that is sensitive to the data voltage Dm may be set to be relatively gentle, and control of gradation power in the low gradation may be maintained, and the slope a2 in the high gradation region that is relatively insensitive to the data voltage Dm may be set to be steep so that the driving range of the data voltage Dm may be reduced.

In an embodiment described above, a display device that may include a plurality of lower metal layers corresponding to a plurality of channel areas, respectively, so that the characteristics of picture quality may be increased and power consumption may be reduced, may be implemented. Of course, the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a substrate;
a light-emitting diode disposed on the substrate;
a driving transistor disposed on the substrate, electrically connected to the light-emitting diode, and comprising a plurality of channel areas; and
a plurality of lower metal layers arranged between the substrate and the driving transistor and overlapping the plurality of channel areas, respectively.

2. The display device of claim 1, wherein the plurality of lower metal layers is spaced apart from each other.

3. The display device of claim 1, wherein the plurality of channel areas comprises a first channel area and a second channel area, and
the plurality of lower metal layers comprises:
a first lower metal layer, which overlaps the first channel area and to which a first voltage is applied; and
a second lower metal layer, which overlaps the second channel area and to which a second voltage having a different magnitude from a magnitude of the first voltage is applied.

4. The display device of claim 3, wherein the first lower metal layer and the second lower metal layer are arranged in different layers.

5. The display device of claim 4, wherein the first lower metal layer and the second lower metal layer overlap each other.

6. The display device of claim 3, wherein the first lower metal layer and the second lower metal layer are arranged in a same layer.

7. The display device of claim 6, wherein each of the first lower metal layer and the second lower metal layer extends in a first direction.

8. The display device of claim 3, wherein a ratio of a width of the second channel area to a length of the second channel area is greater than a ratio of a width of the first channel area to a length of the first channel area.

9. The display device of claim 1, further comprising a gate conductive layer disposed on the driving transistor,
wherein the gate conductive layer overlaps the plurality of channel areas.

10. The display device of claim 1, wherein the driving transistor comprises a silicon semiconductor layer.

11. A display device comprising:
a substrate;
a first lower metal layer disposed on the substrate;
a second lower metal layer disposed on the substrate and spaced apart from the first lower metal layer;
a driving transistor disposed on the first lower metal layer and the second lower metal layer and comprising a silicon semiconductor layer; and
a gate conductive layer disposed on the silicon semiconductor layer,
wherein the driving transistor comprises a first channel area overlapping the first lower metal layer and a second channel area overlapping the second lower metal layer.

12. The display device of claim 11, wherein the first lower metal layer and the second lower metal layer are arranged in different layers.

13. The display device of claim 11, wherein the first lower metal layer and the second lower metal layer are arranged in a same layer.

14. The display device of claim 13, wherein the first lower metal layer and the second lower metal layer do not overlap each other.

15. The display device of claim 13, wherein each of the first lower metal layer and the second lower metal layer extends in a first direction.

16. The display device of claim 11, wherein the gate conductive layer overlaps the first channel area and the second channel area.

17. The display device of claim 11, wherein a first voltage is applied to the first lower metal layer, and a second voltage greater than the first voltage is applied to the second lower metal layer.

18. The display device of claim 17, wherein the driving transistor is a p-channel metal oxide semiconductor.

19. The display device of claim 18, wherein a ratio of a width of the second channel area to a length of the second channel area is greater than a ratio of a width of the first channel area to a length of the first channel area.

20. The display device of claim 11, wherein the first lower metal layer and the second lower metal layer comprise a same material.
